(19) United States
(12) Patent Application Publication
(10) Pub. No.: US 2007/0221979 A1
(43) Pub. Date: Sep. 27, 2007

(54) Method for production of memory devices and semiconductor memory device

(76) Inventors: Dirk Caspary, Dresden (DE); Stefano Parascandola, Dresden (DE); Stephan Riedel, Dresden (DE)

Correspondence Address: SLATER & MATSIL LLP, 17950 PRESTON ROAD, SUITE 1000, DALLAS, TX, 75252, US

(21) Appl. No.: 11/386,456

(22) Filed: Mar. 22, 2006

(51) Int. Cl. H01L 29/792; H01L 21/336

(52) U.S. Cl. 257/314; 438/304; 438/596; 438/287; 257/324

(57) ABSTRACT

At least one memory layer is provided on a substrate surface. A plurality of parallel conductor strips is formed from electrically conductive material above the memory layer. Sidewalls of the conductor strips are provided with spacers of an electrically conductive material.

### TECHNICAL FIELD

This invention concerns memory devices, especially charge-trapping memory devices, comprising an array of memory cells with implanted source/drain regions.

### BACKGROUND

The memory cells of a semiconductor memory device comprise a transistor structure with a channel region at a main surface of a semiconductor substrate. The channel region is located between source/drain regions and is controlled by an electrically conductive gate electrode that is electrically insulated from the channel region by a gate dielectric. The insulating material between the gate electrode and the channel can be a memory layer sequence of dielectric materials, at least one dielectric material being suitable for charge trapping. The charge-trapping layer is provided as a storage means. The stored charge changes the threshold voltage of the transistor structure so that different programmed states can be distinguished. The source/drain regions can be formed by an implantation of a dopant, which is preferably performed after the structuring of the gate electrodes. The gate electrodes are used as an implantation mask.

Spacer constructions on the sidewalls of the gate electrodes are used to enlarge the channel length. The spacers are formed of dielectric material and extend the lateral dimension of the gate electrodes in the direction of the channel. The lateral boundaries of the source/drain regions towards the channel, the junctions, are located approximately under the sidewalls of the gate electrodes. If a very low thermal budget is employed during the manufacturing process, the doping atoms diffuse only a small distance below the gate electrode. The overlaps of the gate electrodes over the junctions may be too small in this case; a sufficient overlap of the gate electrode over the source/drain regions is favorable to the device performance.

If the storage density is considerably increased, the small lateral dimensions lead to an increased aspect ratio of the structure of the gate electrodes and wordlines. Therefore, it is increasingly difficult to form the sidewall spacers by a deposition of a conformal layer and subsequent anisotropic etching. Plasma etches produce polymers, which have to be removed before the implantation of doping atoms takes place. These problems cannot be avoided if the usual process steps are applied.

### SUMMARY OF THE INVENTION

The method for production of memory devices comprises providing a substrate having a main surface, providing at least one memory layer on the surface, forming a plurality of parallel conductor strips from electrically conductive material above the memory layer, applying a conformal layer of an electrically conductive material, preferably the same material as the electrically conductive material of the conductor strips, and etching the conformal layer to form spacers on sidewalls of the conductor strips.

These and other features of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section of an intermediate product of a first embodiment;

FIG. 2 shows the cross-section according to FIG. 1 after the deposition of a conformal layer;

FIG. 3 shows the cross-section according to FIG. 2 after the formation of spacers;

FIG. 4 shows the cross-section according to FIG. 3 for an implantation step;

FIG. 5 shows the cross-section according to FIG. 4 after the application of a covering dielectric material;

FIG. 6A shows the cross-section according to FIG. 5 after the removal of the hardmask;

FIG. 6B shows the cross-section according to FIG. 6A after etching back the conductive material;

FIG. 7 shows the cross-section according to FIG. 6A after the application of a further layer of electrically conductive material;

FIG. 8 shows the cross-section according to FIG. 3 of a second embodiment;

FIG. 9 shows the cross-section according to FIG. 4 of the second embodiment;

FIG. 10 shows the cross-section according to FIG. 5 of the second embodiment;

FIG. 11 shows the cross-section according to FIG. 10 after a planarization step and the removal of the hardmask;

FIG. 12 shows the cross-section according to FIG. 11 after the application of a further layer of electrically conductive material;

FIG. 13 shows a cross-section of an intermediate product of a further variant of the production method;

FIG. 14 shows the cross-section according to FIG. 13 after the application of a conformal layer;

FIG. 15 shows the cross-section according to FIG. 14 after the formation of sidewall spacers;

FIG. 16 shows the cross-section according to FIG. 15 for an implantation step;

FIG. 17 shows the cross-section according to FIG. 16 after the application of a covering dielectric material;

FIG. 18 shows the cross-section according to FIG. 17 after a planarization step and the removal of the hardmask;

FIG. 19 shows the cross-section according to FIG. 18 after a partial removal of the residual dielectric material; and

FIG. 20 shows the cross-section according to FIG. 19 after the application of electrically conductive material.

### DETAILED DESCRIPTION OF ILLUSTRATIVE EMBODIMENTS

In one aspect, the method for production of memory devices comprises providing a substrate having a main surface, providing at least one memory layer on the surface, forming a plurality of parallel conductor strips from electrically conductive material above the memory layer, applying a conformal layer of an electrically conductive material, preferably the same material as the electrically conductive material of the conductor strips, and etching the conformal layer to form spacers on sidewalls of the conductor strips. The electrically conductive materials of the conductor strips and the spacers are preferably in both cases doped polysilicon.

In a further aspect, the method for production of memory devices comprises providing a substrate having a main surface, applying at least one dielectric layer on the surface, forming conductor strips from electrically conductive material above the dielectric layer or layers, providing the conductor strips with sidewalls, applying a conformal layer of an electrically conductive material, preferably the same material as the material of the conductor strips, etching the conformal layer to form spacers on the sidewalls, and implanting a dopant provided for source/drain regions in areas that are located between the conductor strips and are left free by the spacers. The electrically conductive materials of the conductor strips and the spacers are preferably in both cases doped polysilicon.

In a further aspect, the method for production of memory devices comprises providing a substrate having a main surface, applying at least one dielectric layer on the surface, forming conductor strips from electrically conductive material above the dielectric layer, applying spacers on sidewalls of the conductor strips by a deposition of an electrically conductive material, preferably the same electrically conductive material as the material of the conductor strips, and implanting a dopant provided for source/drain regions in areas that are located between the conductor strips and are left free by the spacers. The electrically conductive materials of the conductor strips and the spacers are preferably doped polysilicon, and the spacers are selectively grown on the sidewalls.

In a further aspect, the method for production of memory devices, comprises providing a substrate having a main surface, applying at least one dielectric layer on the surface, forming a hardmask comprising parallel strips with upper surfaces and sidewalls above the dielectric layer or layers, applying a conformal layer on the hardmask, etching the conformal layer to form spacers on the sidewalls of the hardmask, implanting a dopant provided for source/drain regions in areas that are left free by the hardmask and the spacers, covering the hardmask with dielectric material, planarizing the dielectric material so that the upper surfaces of the hardmask are uncovered, removing the hardmask, applying an electrically conductive material, thereby filling spaces that had been occupied by the hardmask, and structuring the electrically conductive material to form conductor tracks and gate electrodes.

The semiconductor memory device, which can be produced by the disclosed methods, comprises a substrate having a main surface, a memory layer on the surface, gate electrodes formed of electrically conductive material above the surface, source/drain regions formed in the substrate at the main surface, the gate electrodes having sidewalls neighboring the source/drain regions, and spacers of an electrically conductive material, preferably the same material as the material of the gate electrodes, the spacers being arranged on the sidewalls of the gate electrodes. The gate electrodes and the spacers are preferably both doped polysilicon.

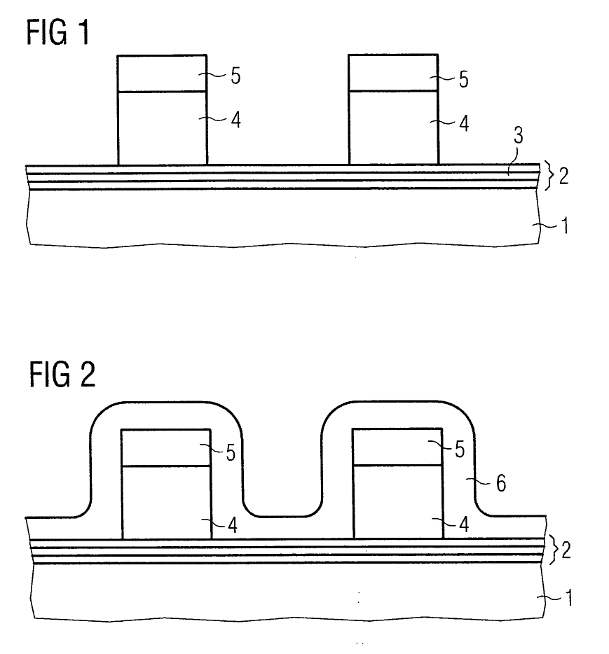

FIG. 1 is a cross-section of an intermediate product, which shows a substrate 1 of semiconductor material having a main surface. On the main surface, there is at least one layer of a dielectric material, which is provided as gate dielectric. The dielectric layers 2 can especially comprise a memory layer 3 of a dielectric material that is suitable for charge trapping. Above the dielectric layer or layers 2, conductor strips 4 are formed from a layer of electrically conductive material, on which a hardmask 5 is applied. The hardmask is used to structure the electrically conductive layer to form the conductor strips 4, which are provided for the gate electrodes of the transistor structures of the individual memory cells. According to the intended matrix arrangement of the memory cells, the conductor strips are preferably formed parallel at a distance from one another. The hardmask can be silicon nitride, for example. At this stage of the method, an implantation of doping atoms can optionally be performed, especially an implantation provided for pocket implants, for example, using the hardmask and conductor strips as a mask.

FIG. 2 shows the cross-section according to FIG. 1 after the application of a conformal layer 6, which is provided for the formation of spacers on the sidewalls of the conductor strips 4 and is preferably of the same electrically conductive material as the conductor strips 4, preferably polysilicon. The electrically conductive material of the conformal layer 6 is then anisotropically etched back to form sidewall spacers along the sidewalls of the conductor strips 4.

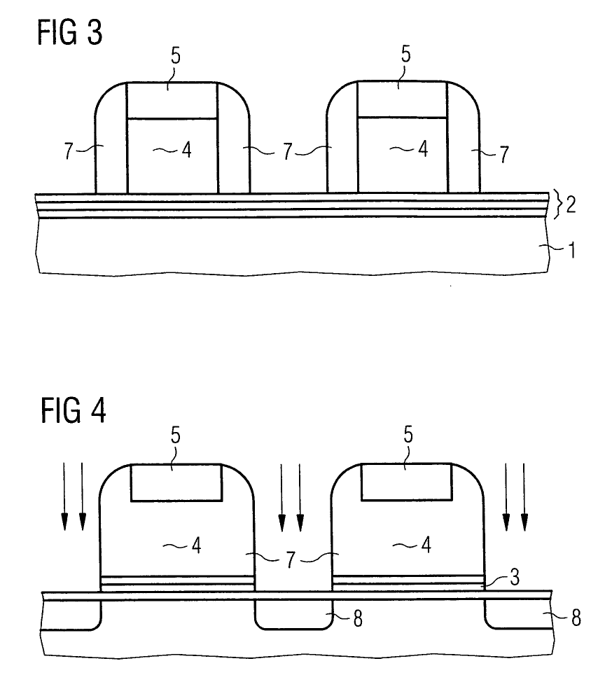

FIG. 3 shows the intermediate product after the formation of the spacers 7 on the sidewalls of the conductor strips 4, including the sidewalls of the hardmask 5, which is still present on the upper surfaces of the conductor strips 4.

FIG. 4 is a cross-section according to FIG. 3 and shows an implantation of a dopant to form source/drain regions 8. The direction of the implantation is indicated in FIG. 4 by the arrows pointing downwards. The limiting contours between the cross-section of the conductor strips 4 and the spacers 7 are left out in FIG. 4 to indicate that, in this preferred embodiment, the spacers 7 are of the same electrically conductive material as the conductor strips 4. If the gate dielectric is formed of a layer sequence of dielectric materials, especially an oxide-nitride-oxide layer sequence provided for charge trapping, the bare upper dielectric layers including the memory layer 3 can be removed before the implantation step. This is also shown in FIG. 4 as an example. Then the structure is covered with a layer of dielectric material.

FIG. 5 shows the next intermediate product after the application of the dielectric material 9. The horizontal broken line in FIG. 5 indicates a planarization level 10, down to which the dielectric material 9 is removed in a subsequent planarization step. The hardmask is then removed; a further portion of the dielectric material 9 can also be removed in this step.

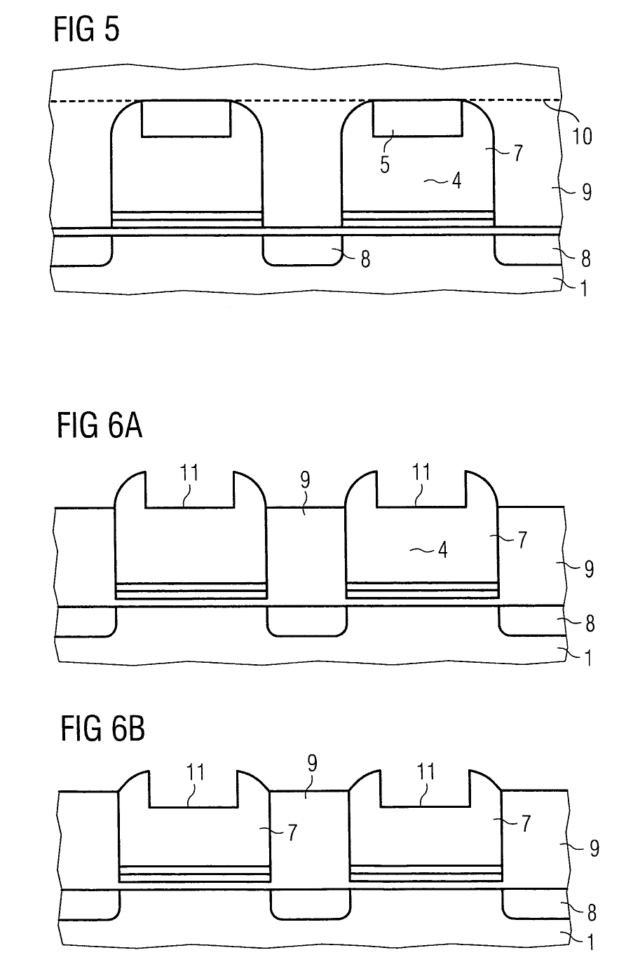

FIGS. 6A and 6B show the result of the removal of the dielectric material and hardmask from the upper surface 11 of the conductor strips 4 without (FIG. 6A) or with (FIG. 6B) a further slight pull-back of the electrically conductive material of the conductor strips 4 and the spacers 7. The slight removal of the electrically conductive material according to FIG. 6B is optional and can be performed by a selective wet etching of the conductive material, especially if it is polysilicon, with respect to the adjacent dielectric material. The contours between the lowest dielectric layer and the dielectric material 9 are left out in the figures to indicate that the material of the lowest dielectric layer and the dielectric material 9 can be the same, preferably oxide.

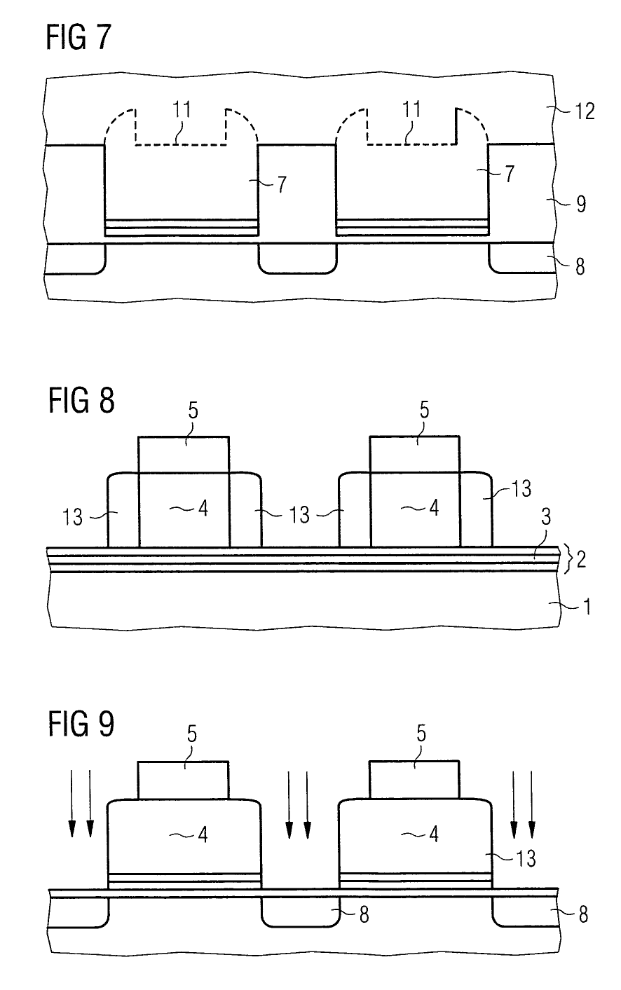

FIG. 7 shows the cross-section after the application of a layer 12 of electrically conductive material for the variant according to FIG. 6A; the corresponding cross-section for the variant according to FIG. 6B is obvious from the figures and not shown separately. The layer 12 of electrically conductive material, which is preferably polysilicon, electrically connects the upper surface 11 of the conductor strips. The layer 12 is subsequently structured to form wordlines running parallel at a distance from one another, which are provided to address the gate electrodes, and the conductor strips 4 are structured accordingly to form the separate gate electrodes of the individual memory cells.

Instead of the formation of the spacers by conformal deposition of the spacer material and subsequent anisotropic etching, the spacers can also be formed by a direct deposition of the electrically conductive material. This variant of the manufacturing process also starts with the intermediate product according to FIG. 1.

FIG. 8 shows the cross-section after the deposition of the spacers. The spacers 13 are formed by a deposition of the electrically conductive material on the sidewalls of the conductor strips 4. The material of the spacers is preferably the same as the material of the conductor strips 4. Polysilicon is especially preferred, which can be selectively grown on the polysilicon sidewalls of the conductor strips 4. This means that the dielectric surfaces are kept free from the polysilicon. This variant of the method is especially preferred because there is no need for an etching step to form the spacers. Cleaning and planarization problems are thus avoided.

The dopant provided for the source/drain regions 8 can then be implanted, as shown in FIG. 9. Here again, the boundaries between the conductor strips 4 and the spacers 13 have been left out to indicate that the electrically conductive materials of the conductor strips 4 and the spacers 13 are preferably the same.

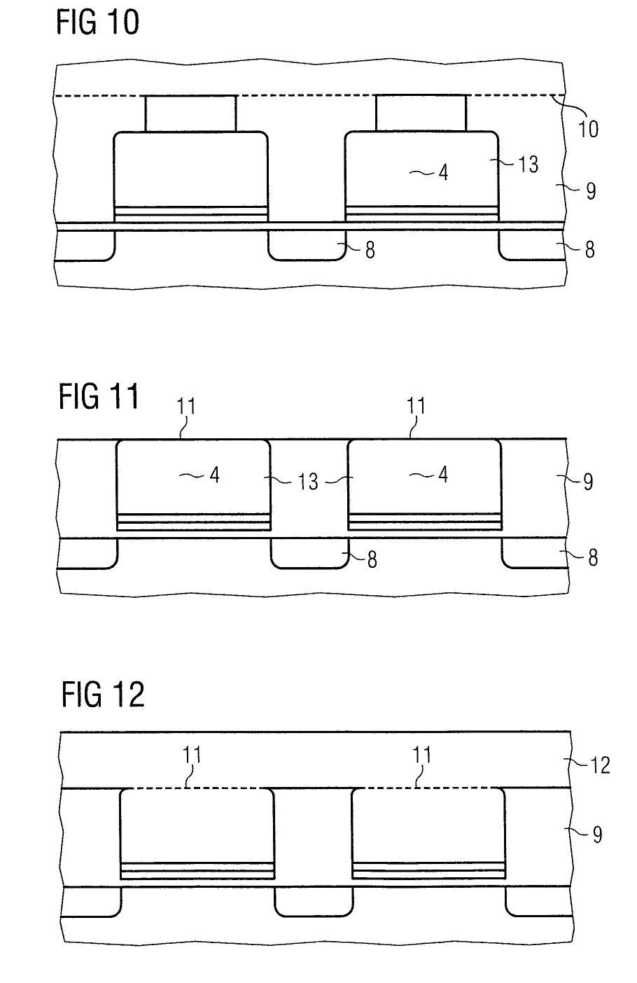

FIG. 10 shows the cross-section of the intermediate product after the application of the covering dielectric material 9, corresponding to the cross-section of FIG. 5. The dielectric material 9 is planarized down to the planarization level 10 at the upper surfaces of the hardmask. Then the hardmask is removed in a way that keeps the upper surface planar. This renders the intermediate product according to the cross-section of FIG. 11, which shows that the upper surface 11 of the conductor strips 4 is laid bare.

FIG. 12 shows the cross-section according to FIG. 11 after the application of the layer 12 of electrically conductive material, which contact-connects the upper surfaces 11 of the conductor strips. This product corresponds to the product according to FIG. 7. Like the preceding embodiment, the layer 12 of electrically conductive material is structured into wordlines, and the conductor strips 4 are structured into separate gate electrodes.

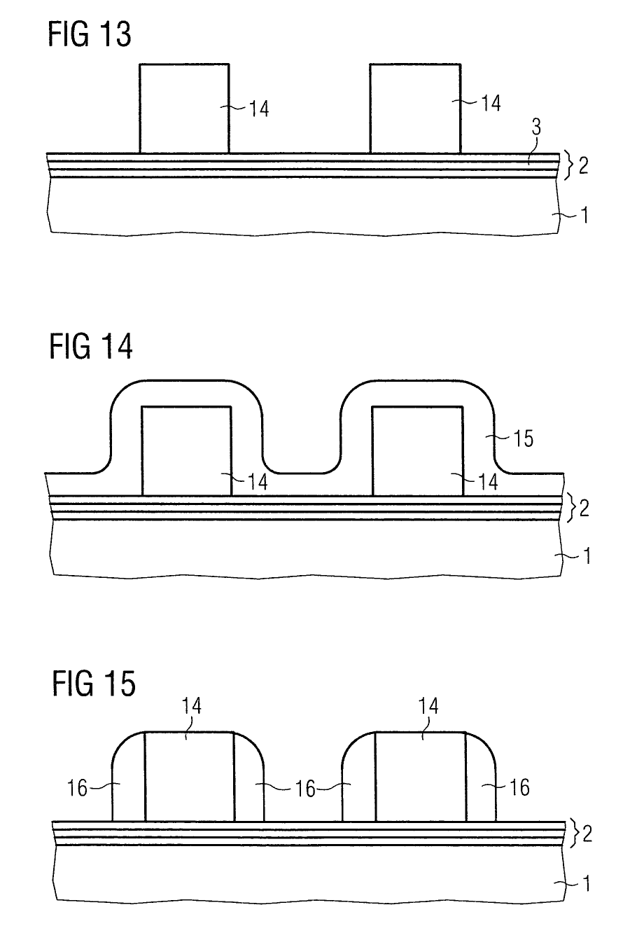

FIG. 13 shows the cross-section of an intermediate product of a further method, which does not apply the initial conductor strips 4. Instead, a hardmask 14, preferably of silicon nitride, is applied and structured into parallel strips, whose shape is comparable to the structure of the conductor strips 4 of the preceding embodiments.

FIG. 14 shows the cross-section according to FIG. 13 after the application of a conformal layer 15, which is chosen to be selectively etchable with respect to an electrically conductive material provided for the gate electrodes. The conformal layer 15 is preferably the same material as the hardmask, especially silicon nitride. The conformal layer 15 is then anisotropically etched back to form sidewall spacers on the sidewalls of the strips of the hardmask 14.

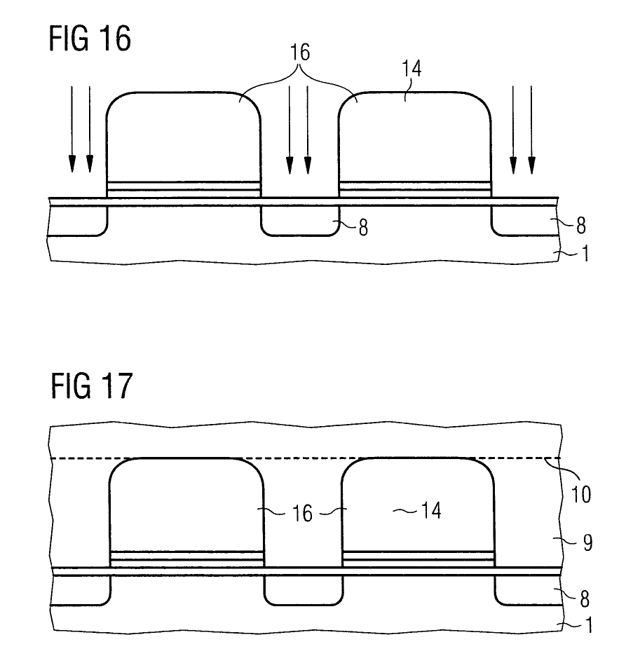

FIG. 15 shows the structure thus obtained with the strips of the hardmask 14 and the sidewall spacers 16 shown in cross-section.

FIG. 16 shows the cross-section according to FIG. 15 for the implantation step to form the doped source/drain regions 8. Here again, the contours between the hardmask 14 and the spacers 16 are left out to indicate that both materials can be nitride.

FIG. 17 shows the cross-section according to FIG. 16 after the application of a covering dielectric material 9; the planarization level 10 is again indicated with the horizontal broken line. The dielectric material 9 is chosen so that the material of the hardmask and the spacers can be removed selectively with respect to the dielectric material 9. If the hardmask and the spacers are nitride, the dielectric material 9 is preferably oxide. Then the hardmask 14 and the spacers 16 are selectively removed.

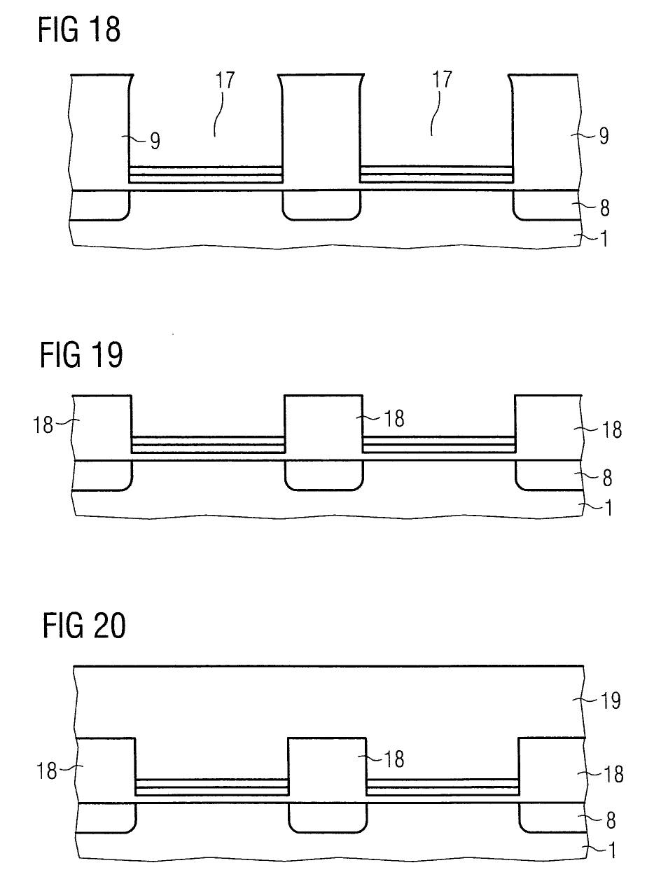

FIG. 18 shows the cross-section after the removal of the hardmask and the spacers, which renders the openings 17 in the dielectric material 9 above the areas in which the gate electrodes are to be located.

FIG. 19 shows the result of a further process step, which is optional and reduces the layer thickness of the dielectric material 9. The dielectric material 9 is partially removed except for the residual dielectric material 18, which maintains a smooth upper surface.

FIG. 20 shows the cross-section according to FIG. 19 after the application of an electrically conductive material 19, which is provided both for the gate electrodes and the wordlines. The electrically conductive material 19 is subsequently structured accordingly.

The various embodiments show that by this method a structure of the gate electrode is obtained that provides a sufficient overlap over the source/drain regions, even if only a very restricted diffusion of the doping atoms takes place due to a limited thermal budget. This is made possible since, as can clearly be seen from FIGS. 7, 12, and 20, the lower edges of the gate electrodes including the electrically conductive spacers are situated immediately above the lateral junctions of the source/drain regions. Thus, there is no dielectric spacer between the gate electrode and the source/drain junction. In this way, the problem of an insufficient overlap of the gate electrodes over the source/drain regions is avoided.

Gate electrodes, spacers, and wordlines can be formed of polysilicon by means of standard processing steps of semiconductor technology. This method is especially suitable for the production of charge-trapping memory devices of extremely shrunk dimensions.

Although the present invention and its advantages have been described in detail, it should be understood that various changes, substitutions and alterations can be made herein without departing from the spirit and scope of the invention as defined by the appended claims.

What is claimed is:

1. A method of producing a memory device, the method comprising:
providing a substrate having a main surface;
providing at least one memory layer on said main surface;
forming a plurality of parallel conductor strips from electrically conductive material on said main surface above said at least one memory layer, said plurality of parallel conductor strips being provided with sidewalls;
applying a conformal layer of an electrically conductive material; and
etching said conformal layer to form spacers on said sidewalls of the plurality of parallel conductor strips.

2. The method according to claim 1, further comprising implanting a dopant provided for source/drain regions using the plurality of parallel conductor strips and the spacers as a mask.

3. The method according to claim 1, wherein the plurality of parallel conductor strips and the spacers are formed from the same electrically conductive material.

4. The method according to claim 1, wherein the at least one memory layer comprises a dielectric material that is suitable for charge trapping.

5. The method according to claim 1, further comprising:
applying a layer of electrically conductive material in contact with said plurality of parallel conductor strips; and
structuring said layer to form conductor tracks and said conductor strips to form gate electrodes.

6. The method according to claim 1, wherein forming said plurality of parallel conductor strips comprises:
applying a layer of the electrically conductive material;
applying a hardmask on said layer; and
using said hardmask to structure said layer into said conductor strips.

7. A method of producing a memory device, the method comprising:
providing a substrate having a main surface;
applying at least one dielectric layer on said main surface;
forming conductor strips from electrically conductive material above said at least one dielectric layer, the conductor strips having sidewalls;
applying a conformal layer of an electrically conductive material;
etching the conformal layer to form spacers on said sidewalls; and
implanting a dopant provided for source/drain regions in areas that are located between said conductor strips and are left free by said spacers.

8. The method according to claim 7, wherein the at least one dielectric layer comprises at least one dielectric material that is suitable for charge trapping.

9. The method according to claim 7, wherein the conductor strips and the spacers are formed from the same electrically conductive material.

10. The method according to claim 7, further comprising:
applying a layer of electrically conductive material in contact with said conductor strips; and
structuring said layer to form conductor tracks and said conductor strips to form gate electrodes.

11. The method according to claim 7, further comprising:
after the implantation of the dopant, covering the conductor strips with dielectric material;
planarizing said dielectric material;
exposing an upper surface of the conductor strips;
applying a further layer of an electrically conductive material, said further layer contact-connecting the conductor strips; and
structuring said further layer to form conductor tracks and said conductor strips to form gate electrodes.

12. The method according to claim 8, further comprising, before implanting the dopant, removing dielectric materials including the at least one dielectric material that is suitable for charge trapping in areas that are located between the conductor strips and are left free by the spacers.

13. The method according to claim 9, wherein the conductor strips and the spacers are formed from polysilicon.

14. The method according to claim 11, further comprising, before applying the further layer of the electrically conductive material, etching the electrically conductive material of the conductor strips and the spacers back, selectively with respect to the dielectric material.

15. A method of producing a memory device, the method comprising:
providing a substrate having a main surface;
applying at least one dielectric layer on said main surface;
forming a hardmask comprising parallel strips with upper surfaces and sidewalls above said at least one dielectric layer;
applying a conformal layer on said hardmask;
etching the conformal layer to form spacers on said sidewalls;
implanting a dopant provided for source/drain regions in areas that are left free by said hardmask and said spacers;
covering the hardmask with dielectric material;
planarizing said dielectric material so that said upper surfaces of said hardmask are uncovered;
removing said hardmask;
applying an electrically conductive material, thereby filling spaces that had been occupied by the hardmask; and
structuring said electrically conductive material to form conductor tracks and gate electrodes.

16. The method according to claim 15, wherein applying said electrically conductive material comprises depositing polysilicon.

17. The method according to claim 15, wherein applying the at least one dielectric layer on the main surface of the substrate comprises applying a layer sequence of dielectric materials comprising at least one dielectric material that is suitable for charge trapping.

18. The method according to claim 15, further comprising, before implanting the dopant, removing dielectric materials, including the at least one dielectric material that is suitable for charge trapping, in areas that are left free by the hardmask and the spacers.

19. The method according to claim 15, further comprising, after removing the hardmask and before applying the electrically conductive material, removing upper portions of the dielectric material.

20. The method according to claim 15, wherein said hardmask and said spacers are formed from nitride.

21. A semiconductor memory device, comprising:
a substrate having a main surface;
a memory layer on said main surface;
gate electrodes formed of electrically conductive material above said main surface;
source/drain regions formed in said substrate at said main surface, said gate electrodes having sidewalls neighboring said source/drain regions; and
spacers of an electrically conductive material being arranged on said sidewalls.

22. The semiconductor memory device according to claim 21, wherein said gate electrodes and said spacers are formed from the same electrically conductive material.

23. The semiconductor memory device according to claim 22, wherein said gate electrodes and said spacers are formed from polysilicon.

24. The semiconductor memory device according to claim 21, wherein said memory layer comprising a dielectric material that is suitable for charge trapping.
